(19) United States
(12) Patent Application Publication
(10) Pub. No.: US 2026/0202890 A1
(43) Pub. Date: Jul. 16, 2026

(54) ELECTRONIC APPARATUS

(71) Applicant: LENOVO JAPAN LLC, YOKOHAMA (JP)

(72) Inventors: Yuki Saigusa, YOKOHAMA (JP); Yusuke Onoue, YOKOHAMA (JP); Kanya Sugitani, YOKOHAMA (JP); Makoto Hirata, YOKOHAMA (JP)

(73) Assignee: LENOVO JAPAN LLC, YOKOHAMA (JP)

(21) Appl. No.: 19/230,619

(22) Filed: Jun. 6, 2025

(30) Foreign Application Priority Data
Jan. 15, 2025 (JP) 2025005616

(51) Int. Cl. G06F 1/20; H05K 7/20

(52) U.S. Cl. CPC G06F 1/206; H05K 7/20172; H05K 7/20336

(57) ABSTRACT

An electronic apparatus includes: a board mounted with at least a pair of stud parts and a heating element on a surface thereof; and a thermal module provided to cover the heating element and the surface of the board, the thermal module being fixed to the board by using the stud parts. The thermal module includes a pair of positioning parts that respectively abuts on outer peripheral surfaces of the pair of stud parts, and the pair of positioning parts is able to position the thermal module on the surface of the board in a first direction and a second direction perpendicular to the first direction.

### BACKGROUND OF THE INVENTION

### Field of the Invention

The present invention relates to an electronic apparatus mounted with a thermal module.

### Description of the Related Art

An electronic apparatus such as a laptop PC is mounted with a heating element such as CPU. Such the electronic apparatus is mounted with a thermal module for cooling the heating element (e.g., see Japanese Patent No. 7,371,170).

The thermal module disclosed in Japanese Patent No. 7,371,170 includes a vapor chamber or the like that absorbs and diffuses heat of the heating element, and the vapor chamber is assembled integrally with the left and right fans. For this reason, the thermal module can be easily positioned on a board by fitting the fans into notches provided on both sides of the board.

Meanwhile, considering the miniaturization, space efficiency, etc. of the thermal module, it is also considered that the thermal module that receives the heat of the heating element is configured separately from the fans. In this case, the thermal module cannot be positioned by using the fans, and thus there is a concern about the decrease in the manufacturing efficiency of the electronic apparatus. Note that, even if the thermal module and the fans have the integrated structure, it may be difficult to smoothly position the thermal module due to the layout and space in a chassis.

The present invention has been made in consideration of the problems of the conventional technology, and an object of the present invention is to provide an electronic apparatus that can smoothly position the thermal module and improve the manufacturing efficiency.

### SUMMARY OF THE INVENTION

An electronic apparatus according to an aspect of the present invention includes: a board mounted with at least a pair of stud parts and a heating element on a surface thereof; and a thermal module provided to cover the heating element and the surface of the board, the thermal module being fixed to the board by using the stud parts. The thermal module includes a pair of positioning parts that respectively abuts on outer peripheral surfaces of the pair of stud parts, and the pair of positioning parts is able to position the thermal module on the surface of the board in a first direction and a second direction perpendicular to the first direction.

The above-described aspect of the present invention can smoothly position the thermal module and improve the manufacturing efficiency.

### BRIEF DESCRIPTION OF THE DRAWINGS

FIG. 1 is a schematic plan view illustrating an electronic apparatus according to an embodiment when being viewed from above;

FIG. 2 is a plan view schematically illustrating an internal structure of a chassis;

FIG. 3 is a front view illustrating a thermal module;

FIG. 4 is a back view illustrating the thermal module;

FIG. 5A is a plan view illustrating an operation of positioning the thermal module on a motherboard;

FIG. 5B is a plan view illustrating a state where the thermal module illustrated in FIG. 5A is positioned on the motherboard;

FIG. 6 is a schematic cross-sectional view taken along the line VI-VI in FIG. 5B; and

FIG. 7 is a schematic cross-sectional view taken along the line VII-VII in FIG. 5B.

### DETAILED DESCRIPTION OF THE INVENTION

Hereinafter, a preferred embodiment of an electronic apparatus according to the present invention will be described in detail with reference to the accompanying drawings.

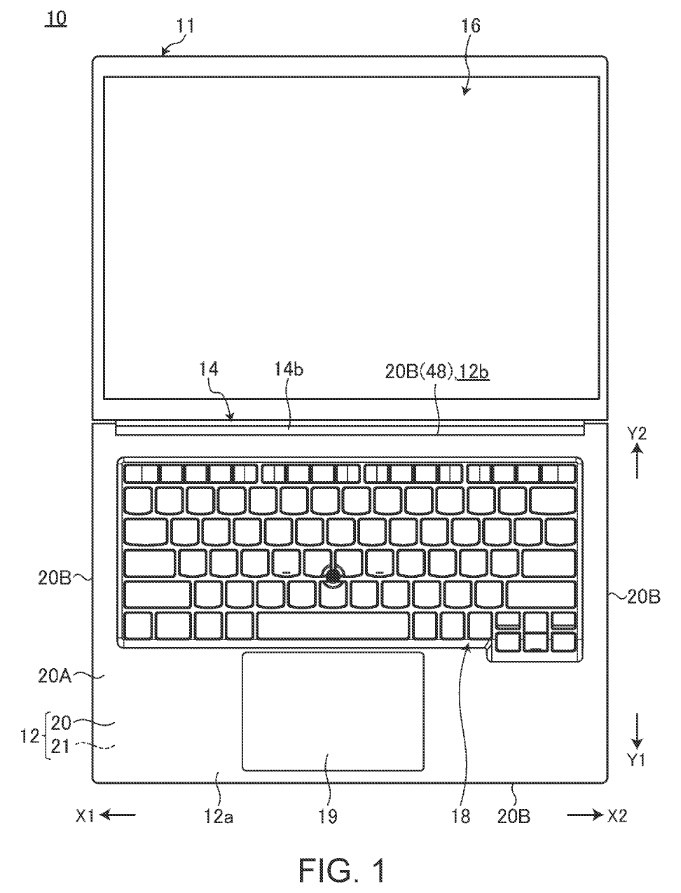

FIG. 1 is a schematic plan view illustrating an electronic apparatus 10 according to an embodiment when being viewed from above. As illustrated in FIG. 1, the electronic apparatus 10 according to the present embodiment is a clamshell laptop PC. The electronic apparatus 10 has a configuration that a cover body 11 and a chassis 12 are connected by a hinge 14 so as to be relatively rotatable. In the present embodiment, the electronic apparatus 10 is exemplified as a laptop PC, but the electronic apparatus may be, for example, a tablet PC, a smartphone, a portable gaming machine, or the like, other than the laptop PC.

The cover body 11 is a thin flat box-shaped chassis. The cover body 11 is mounted with a display 16. The display 16 is an organic electroluminescence display or a liquid crystal display, for example.

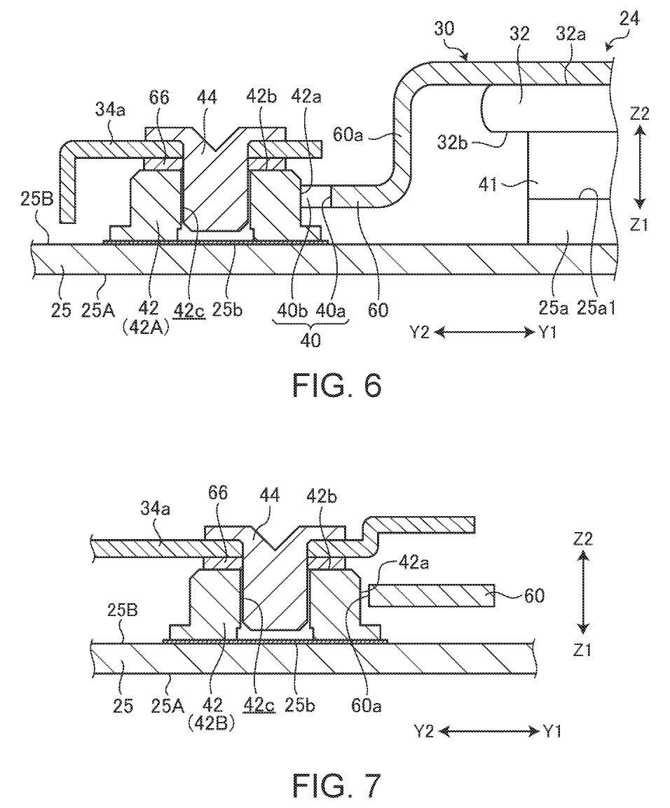

The chassis 12 is a thin flat boxy body. A keyboard 18 and a touch pad 19 are provided on an upper surface (surface 12a) of the chassis 12. Hereinafter, the chassis 12 and components mounted on the chassis are explained assuming that the width direction (left and right) of the chassis 12 is the X1-X2 direction, the depth direction (front and rear) of the chassis 12 is the Y1-Y2 direction, and the thickness direction (top and bottom) of the chassis 12 is the Z1-Z2 direction based on a posture of an operator operating the keyboard 18. The X1-X2 direction may be collectively referred to as the X direction, and the Y1-Y2 direction and the Z1-Z2 direction may be similarly referred to as the Y direction and the Z direction. Moreover, for convenience of explanation, in the thickness direction of the chassis 12, the Z1 direction may be referred to as the bottom, and the opposite direction (the Z2 direction) may be referred to as the top (see FIGS. 6 and 7). These directions are directions defined for convenience of explanation, and thus may be naturally changed depending on the usage state, the installation posture, etc. of the electronic apparatus 10.

The chassis 12 is composed of a chassis member 20 forming the upper surface and the four side surfaces and a cover member 21 forming the lower surface. The chassis member 20 includes standing walls 20B formed on the four peripheral edges of a cover plate 20A forming the surface 12a of the chassis 12. For this purpose, the chassis member 20 has a substantial bathtub shape with the opened lower surface. The cover member 21 has a substantially flat plate shape, and acts as a cover that closes the lower opening of the chassis member 20. The chassis member 20 and the cover member 21 are detachably connected to each other by being superimposed in the thickness direction. The standing walls 20B may be formed on the cover member 21. In this case, the chassis member 20 may be composed of only the cover plate 20A.

The hinge 14 is installed in a recessed hinge arrangement groove 12b formed on the rear edge of the chassis 12 to connect the chassis 12 and the cover body 11. The hinge 14 has, for example, a structure that a hinge shaft acting as the rotation axis is supported at both ends of the chassis in the longitudinal direction.

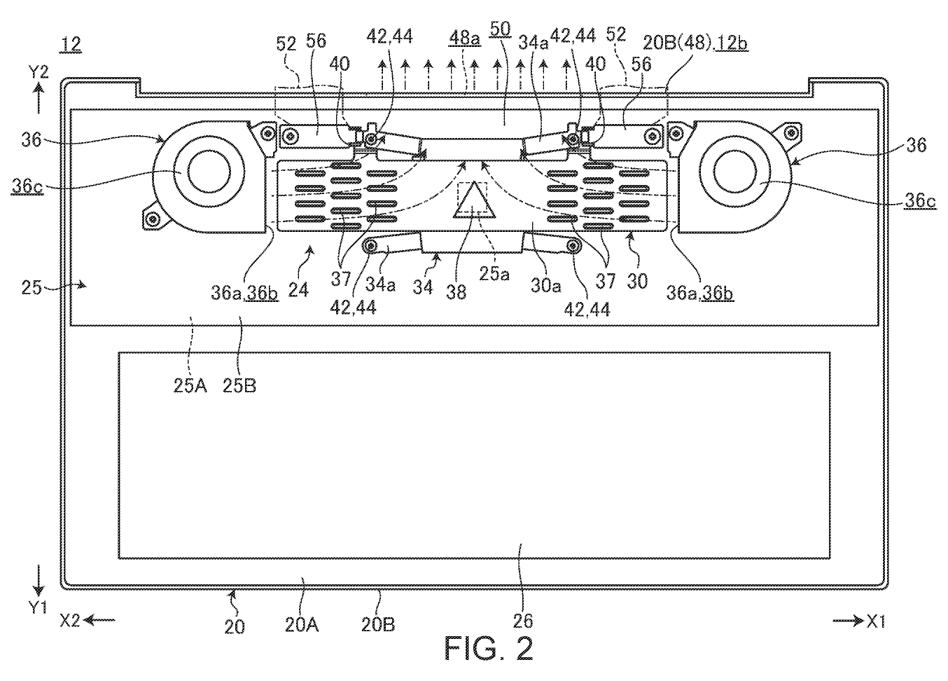

FIG. 2 is a plan view schematically illustrating the internal structure of the chassis 12. FIG. 2 is a diagram illustrating the inside of the chassis member 20 when being viewed from the bottom side after removing the cover member 21.

As illustrated in FIG. 2, a thermal module 24, a motherboard 25, and a battery device 26 are housed inside the chassis 12. Various electronic parts, mechanical parts, and the like are further provided inside the chassis 12.

The motherboard (board in claims) 25 is a circuit board that acts as a main board of the electronic apparatus 10. The motherboard 25 is arranged closer to the Y2 side of the Y1-Y2 direction of the chassis 12 and extends in the X direction. The battery device 26 is a rechargeable battery that acts as a power source of the electronic apparatus 10. The battery device 26 is arranged closer to the Y1 side of the Y1-Y2 direction of the chassis 12 and extends in the X direction.

The motherboard 25 according to the present embodiment is mounted with a central processing unit (CPU) 25a. The motherboard 25 can be mounted with various electronic parts, such as a graphics processing unit (GPU), a memory, and a communication module, in addition to the CPU 25a. The motherboard 25 has, for example, a first surface 25A on the Z1 side of the Z1-Z2 direction that acts as an attaching surface for the chassis member 20 and a second surface 25B on the Z2 side of the Z1-Z2 direction that acts as a mounting surface for the CPU 25a etc.

Next, the thermal module 24 and the configuration associated with this module will be described.

The CPU 25a is a heating element that has the largest amount of heat generation among the electronic parts mounted in the chassis 12. The thermal module 24 can absorb and diffuse heat generated by the CPU 25a and discharge the heat to the outside of the chassis 12. The thermal module 24 may be configured to cool a heating element, such as a GPU, other than the CPU 25a.

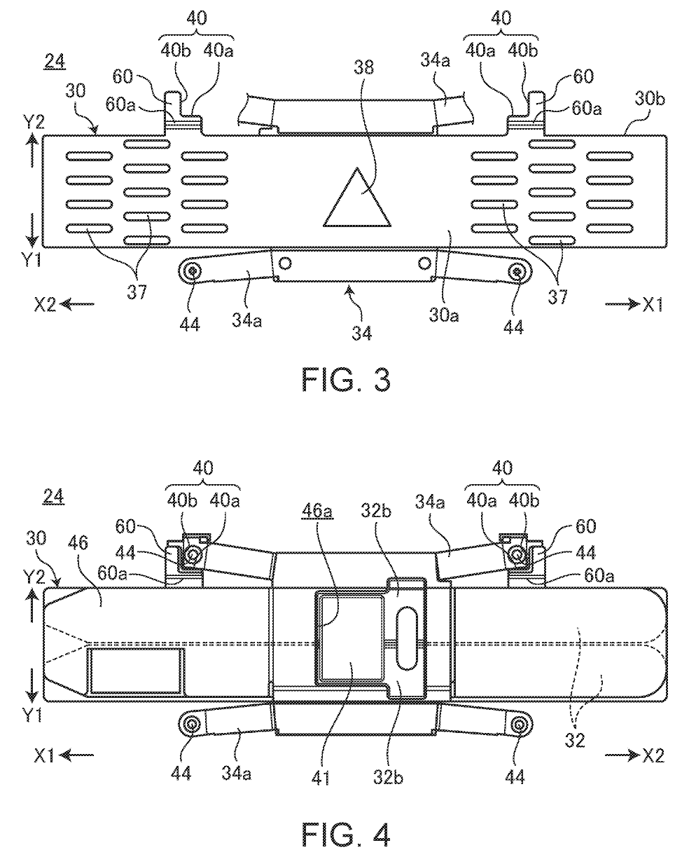

FIG. 3 is a front view illustrating the thermal module 24. FIG. 4 is a back view illustrating the thermal module 24. FIG. 3 is a diagram of the thermal module 24 as viewed from the Z2 side, and FIG. 4 is a diagram of the thermal module 24 as viewed from the Z1 side.

As illustrated in FIGS. 2 to 4, the thermal module 24 include a metal plate 30, heat pipes 32, and a pressing part 34. The metal plate 30, the heat pipes 32 and the pressing part 34 are integrally assembled.

The thermal module 24 is provided so as to cover the CPU 25a and a portion of the second surface 25B of the motherboard 25. The thermal module 24 has a rectangular outer shape that is long in the X direction and narrow in the Y direction, for example. Fans 36 are respectively arranged on both left and right sides of the thermal module 24. The thermal module 24 according to the present embodiment is arranged at a position sandwiched between the left and right fans 36 and 36, but is configured separately from the fans 36.

The metal plate 30 is a thin metallic plate-shaped member formed from material, such as copper and aluminum, having high thermal conductivity. The metal plate 30 according to the present embodiment is a copper plate. The metal plate 30 is arranged to extend in the X direction between the left and right fans 36 and 36. The metal plate 30 is connected to Z2-side surfaces 32a of the heat pipes 32 (see FIG. 6) to cover the heat pipes 32 from the Z2 side. The metal plate 30 and the heat pipes 32 can be joined by soldering, for example. As a result, the metal plate 30 can efficiently receive the heat of the CPU 25a diffused by the heat pipes 32 to diffuse and radiate the heat.

A plurality of fins 37 and an airflow rectifying member 38 can be provided on a Z2-side surface 30a of the metal plate 30. The fins 37 can have a bar shape extending in the X direction, for example. The fins 37 increase a surface area of the metal plate 30 to enhance heat dissipation efficiency. The airflow rectifying member 38 is provided in a central portion of the metal plate 30 in the longitudinal direction. The airflow rectifying member 38 is a member that smoothly directs air, which is discharged from discharge ports 36b of the left and right fans 36 and flows along the surface 30a, toward an exhaust port 48a of the chassis 12. The airflow rectifying member 38 can be composed from a triangular copper block having a vertex facing the Y2 side, for example.

The metal plate 30 according to the present embodiment includes positioning parts 40 for positioning the thermal module 24 on the second surface 25B of the motherboard 25, and the details will be described later.

The heat pipes 32 are a pipe-shaped heat transport device. The heat pipes 32 can absorb and diffuse the heat of the CPU 25a. The heat pipes 32 have a configuration that a metal pipe is squashed thinly and flatly to form an elliptical cross section and working fluid is sealed in an inner sealed space. As an example, the working fluid includes water, chlorofluorocarbon alternative, acetone, butane, or the like. In the present embodiment, the two heat pipes 32 that extend in the X direction are arranged in the Y direction in parallel. The number of the heat pipes 32 may be one or three or more. Instead of the heat pipes 32, a vapor chamber that is a plate-shaped heat transport device made by substantially forming the heat pipes 32 into a plate shape may be employed.

The heat pipes 32 are stacked between the CPU 25a and the metal plate 30. For each of the heat pipes 32, the vicinity of the center in the longitudinal direction overlaps the CPU 25a in the Z direction and a Z1-side surface 32b is connected to a top surface 25a1 of the CPU 25a (see FIG. 6).

In the present embodiment, a thermal conductive member 41 is positioned between the heat pipes 32 and the CPU 25a (see FIGS. 4 and 6). The thermal conductive member 41 is a copper plate that has substantially the same surface area as that of the top surface 25a1, for example. The thermal conductive member 41 has a high degree of flatness to improve heat transfer efficiency between the surfaces 32b of the heat pipes 32 and the top surface 25a1 of the CPU 25a. Thermal conductive grease etc. can be applied to both surfaces of the thermal conductive member 41. The thermal conductive member 41 may be omitted.

The pressing part 34 is a part for pressing the thermal module 24 against the CPU 25a. Specifically, the pressing part 34 is a spring part that presses the heat pipes 32 against the CPU 25a while interposing the thermal conductive member 41 therebetween. The pressing part 34 always biases the thermal module 24 toward the second surface 25B of the motherboard 25. The pressing part 34 includes a pair of flat spring members 34a and 34a in the Y direction. The flat spring member 34a has a central portion connected to a thin metal frame fixed to the Z1-side surfaces 32a of the heat pipes 32, for example, and presses the heat pipes 32 against the CPU 25a via the metal frame. The metal frame is provided to surround the CPU 25a inside the frame, and is fixed to the surfaces 32b by soldering etc.

Both ends of each of the flat spring members 34a and 34a are fastened and fixed to stud parts 42 mounted on the second surface 25B of the motherboard 25 by using screws 44 (see FIGS. 6 and 7). In FIGS. 3 to 5, the illustration of both ends of the Y2-side flat spring member 34a is omitted.

The reference number 46 in FIG. 4 indicates a resin sheet for insulation. The resin sheet 46 may employ a synthetic film whose main component is polyethylene terephthalate (PET), for example. The resin sheet 46 is attached to the Z1-side surfaces of the heat pipes 32 and the pressing part 34 to cover a great portion of the Z1-side surface of the thermal module 24. The resin sheet 46 is an insulating sheet that prevents the thermal module 24 from short-circuiting with mounting parts on the motherboard 25. The resin sheet 46 includes a cutout hole 46a in a portion that vertically overlaps the CPU 25a, for example. As a result, the heat pipes 32 can be connected to the CPU 25a through the cutout hole 46a. In FIGS. 6 and 7, the illustration of the resin sheet 46 is omitted.

As illustrated in FIG. 2, the left and right fans 36 are arranged side by side in the X direction to straddle the thermal module 24 therebetween, and face each other. Each of the fans 36 is fixed to the inner surface (the Z2-side surface) of the chassis member 20 by using a screw etc.

The fans 36 include the discharge ports 36b on side surfaces 36a facing each other. The discharge ports 36b of the left and right fans 36 face each other while interposing the thermal module 24 therebetween. As a result, each of the fans 36 can discharge air toward the thermal module 24. Each of the fans 36 includes a suction port 36c on at least a Z2-side end surface among top and bottom end surfaces facing each other in the Z direction. The suction port 36c may be also provided on the Z1-side end surface. The suction port 36c can suck in outside air (cool air) from a ventilation port formed on the bottom surface of the chassis 12, for example. Each of the fans 36 can be configured by a centrifugal fan whose impeller housed inside a housing is rotated by a motor. Each of the fans 36 can discharge the air sucked from the suction port 36c from the discharge port 36b.

As illustrated in FIG. 2, the chassis 12 can include the exhaust port 48a formed on the standing wall 20B (outer wall 48) of the rear edge (the Y2-side edge). The exhaust port 48a is a ventilation port that can discharge air (hot air), which is discharged from the discharge ports 36b of the fans 36 and flows around the motherboard 25 and the thermal module 24, to the outside of the chassis 12.

In case of the present embodiment, the Y2-side standing wall 20B includes the hinge arrangement groove 12b that extends along the longitudinal direction and is recessed to the Y1 side. The outer wall 48 is a bottom wall (front wall) of the hinge arrangement groove 12b. The exhaust port 48a is provided near the center of the outer wall 48 in the longitudinal direction. The exhaust port 48a includes a plurality of small windows that are arranged closely in the X direction, for example. The exhaust port 48a is located between the left and right fans 36 and 36 when the arrangement direction (the X direction) of the fans 36 and 36 is used as a reference. The exhaust port 48a is located on the Y2 side of the airflow rectifying member 38. The standing wall 20B may have a configuration that does not have the hinge arrangement groove 12b. In this case, the exhaust port 48a may be formed in the standing wall 20B itself that is the outer wall.

One-dotted dashed arrows illustrated in FIG. 2 schematically illustrate the flow of air. As illustrated in FIG. 2, in the electronic apparatus 10, air discharged from the discharge ports 36b of the left and right fans 36 cools the motherboard 25 and the thermal module 24 that absorbs and diffuses the heat of the CPU 25a etc. The cooled air is discharged to the outside of the chassis 12 through the exhaust port 48a. In this case, on the second surface 25B side of the motherboard 25, an exhaust path 50 is formed between the left and right stud parts 42 (the screws 44) for fixing the Y2-side flat spring member 34a.

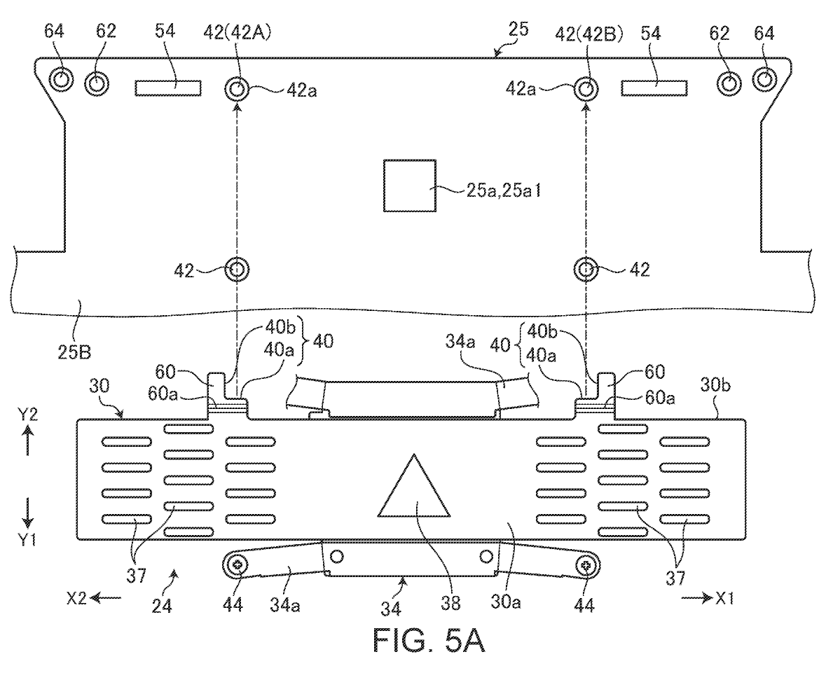

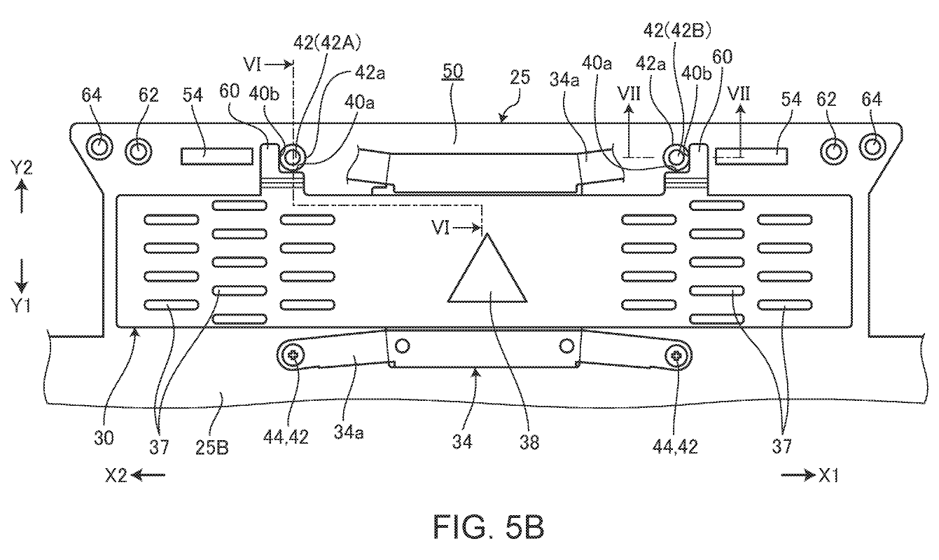

Left and right cables 52 illustrated with two-dotted dashed lines in FIG. 2 are wires for connecting the display 16, a camera, etc. mounted on the cover body 11 to the motherboard 25. The cables 52 are a flexible printed circuit (FPC), for example. The end of each of the cables 52 is connected to a connector 54 (see FIG. 5A) mounted on the second surface 25B of the motherboard 25. This end is pushed down by a bracket 56 supported by the motherboard 25 to prevent the connector 54 from unfastening.

As described above, in the electronic apparatus 10 according to the present embodiment, the thermal module 24 is placed on the motherboard 25 and is screwed. In the thermal module 24, it is necessary that the ends of the flat spring members 34a are aligned with the respective stud parts 42 and the thermal conductive member 41 is applied to the top surface 25a1 of the CPU 25a. However, because the thermal module 24 is arranged so as to cover the CPU 25a and the stud parts 42, it is difficult to position the thermal module on the motherboard 25. Particularly, in the electronic apparatus 10 according to the present embodiment, because the thermal module 24 is configured separately from the fans 36, it is also not possible to position the thermal module and the motherboard 25 by using the fans 36. As a result, there is a concern that the assembly work of the thermal module 24 onto the motherboard 25 takes time to decrease the manufacturing efficiency of the electronic apparatus 10.

Next, a positioning structure of the thermal module 24 will be described.

FIG. 5A is a plan view illustrating an operation of positioning the thermal module 24 on the motherboard 25. FIG. 5B is a plan view illustrating a state where the thermal module 24 illustrated in FIG. 5A is positioned on the motherboard 25. FIG. 6 is a schematic cross-sectional view taken along the line VI-VI in FIG. 5B. FIG. 7 is a schematic cross-sectional view taken along the line VII-VII in FIG. 5B.

As illustrated in FIGS. 2 to 7, the thermal module 24 includes a pair of the positioning parts 40 and 40. The positioning parts 40 position the thermal module 24 on the second surface 25B of the motherboard 25 in the X direction (first direction in claims) and the Y direction (second direction in claims) perpendicular to the X direction. Furthermore, the positioning parts 40 are composed of a pair of left and right parts so as to be able to prevent the rotation of the thermal module 24 on the motherboard 25.

The thermal module 24 according to the present embodiment includes the positioning parts 40 formed on the metal plate 30. The positioning parts 40 may be formed on, for example, the pressing part 34 that is another component of the thermal module 24. The positioning parts 40 may be joined to the metal plate 30, the pressing part 34, or the heat pipes 32 by employing the positioning parts as separate parts from the components of the thermal module 24.

The metal plate 30 can extend in the X direction, and include a pair of arm portions 60 and 60 on a Y2-side edge 30b facing the exhaust port 48a. Each of the arm portions 60 is a plate piece that protrudes toward the Y2 side from the edge 30b. Each of the arm portions 60 is positioned to overlap the end of the Y2-side flat spring member 34a on the Z1 side (see FIGS. 2, 4, 6, and 7). As a result, the left and right arm portions 60 are arranged to straddle the exhaust path 50 therebetween.

Each of the positioning parts 40 can have a configuration that the corner of the tip of the corresponding arm portion 60 is cut out in a substantially rectangular shape. Each of the positioning parts 40 includes a first end surface 40a along the X direction and a second end surface 40b along the Y direction. The left and right positioning parts 40 and 40 are formed in a symmetrical shape. Each of the positioning parts 40 can abut the end surfaces 40a and 40b against an outer peripheral surface 42a of the corresponding stud part 42 to position the thermal module 24 in the X and Y directions.

In the left and right positioning parts 40 and 40, the first end surfaces 40a of them are located on the inner sides facing each other, and the second end surfaces 40b of them are located on the outer sides. As a result, the left and right positioning parts 40 and 40 are configured as L-shape members arranged facing each other in a planar view to form a substantially recessed shape as a whole.

Each of the arm portions 60 can include a step portion 60a in the Z direction between the base and the tip. As illustrated in FIG. 6, the step portion 60a is a portion for cranking the arm portion 60 in the Z direction and arranging the positioning part 40 below the metal plate 30 (on the Z1 side).

Next, the stud part 42 is, for example, a cylindrical member mounted by soldering on a ground pattern 25b of the second surface 25B of the motherboard 25 (see FIGS. 6 and 7). The stud part 42 stands up in the Z2 direction from the second surface 25B. The stud part 42 includes an upwardly facing female threaded hole 42c that opens on the top surface 42b, and the screw 44 can be fastened to the hole.

As illustrated in FIGS. 2, 5A, and 5B, the stud parts 42 are respectively provided at positions overlapping the ends of the two flat spring members 34a. As a result, the number of the stud parts 42 according to the present embodiment is four in total. In the present embodiment, the pair of stud parts 42 and 42 for fastening both ends of the Y2-side flat spring member 34a are used for positioning the positioning parts 40. Hereinafter, the stud parts 42 are referred to as "stud parts 42A and 42B" (see FIG. 5A). The stud parts 42A and 42B are arranged side by side in the X direction along the edge 30b of the metal plate 30.

As illustrated in FIG. 6, the metal plate 30 is located above the top surfaces 42b of the stud parts 42A and 42B (on the Z2 side). In other words, the stud parts 42A and 42B are directly mounted on the second surface 25B. On the other hand, the metal plate 30 is mounted on/over the heat pipes 32, the thermal conductive member 41, and the CPU 25a stacked on the second surface 25B. The step portion 60a of the arm portion 60 is a step for filling the Z-direction height difference between the metal plate 30 and the outer peripheral surfaces 42a of the stud parts 42A and 42B. If there is no such the height difference, the step portion 60a may be omitted.

The reference number 62 in FIG. 5A is a stud part for screwing one end of the bracket 56 into the motherboard 25. The reference number 64 in FIG. 5A is a stud part for screwing a portion of the fan 36 into the motherboard 25. The reference number 66 in FIGS. 6 and 7 is a washer for capturing the screw 44 in the flat spring member 34a. The washer 66 may be omitted.

Next, a positioning operation of the thermal module 24 will be described.

As illustrated in FIG. 5A, when the thermal module 24 is assembled to the motherboard 25, the edge 30b side is inclined slightly downward (toward the Z1 side). Then, the thermal module 24 is moved in the Y2 direction, and the left and right positioning parts 40 and 40 are butted against the outer peripheral surfaces 42a of the stud parts 42A and 42B. By doing so, as illustrated in FIG. 5B, the first end surfaces 40a of the left and right positioning parts 40 in the thermal module 24 abut on the outer peripheral surfaces 42a to be positioned in the Y direction. Furthermore, the second end surfaces 40b of the left and right positioning parts 40 in the thermal module 24 abut on or are close to the outer peripheral surfaces 42a to be also positioned in the X direction.

Then, the thermal module 24 is placed on the motherboard 25 by bringing down the opposite side of the edge 30b (toward the Z1 side). As a result, ends (fastening portions) of the flat spring members 34a in the thermal module 24 respectively correspond to the stud parts 42. Moreover, the thermal conductive member 41 abuts the top surface 25a1 of the CPU 25a. Then, the flat spring members 34a are fastened to the stud parts 42 with the screws 44. As a result, the thermal module 24 is fixed to the motherboard 25 in a positioned state within a predetermined tolerance.

Note that the Y1-side flat spring member 34a may be fixed to the motherboard 25 by using a configuration different from the fastening structure by the stud parts 42 for example. Moreover, the thermal module 24 may have a configuration that arm portions same as the arm portions 60 are provided at respective positions on the metal plate 30 and these arm portions are fastened to the stud parts 42, without employing the pressing part 34.

As described above, the electronic apparatus 10 according to the present embodiment includes the motherboard 25, which is mounted with at least one pair of the stud parts 42 and the CPU 25a acting as a heating element on its surface. The electronic apparatus 10 further includes the thermal module 24 that is provided to cover the CPU 25a and the surface of the motherboard 25 and is fixed to the motherboard 25 by using the stud parts 42. The thermal module 24 includes one pair of the positioning parts 40 that respectively abut on the outer peripheral surfaces 42a of the pair of stud parts 42. The pair of positioning parts 40 can position the thermal module 24 on the surface of the motherboard 25 in the first direction (X direction) and the second direction (Y direction) perpendicular to the first direction.

As described above, the electronic apparatus 10 can position the thermal module 24 by using the positioning parts 40 provided on the thermal module 24 and the outer peripheral surfaces 42a of the fastening stud parts 42 of the thermal module 24. For this purpose, the electronic apparatus 10 enables the smooth positioning of the thermal module 24 to improve the manufacturing efficiency.

Particularly, the thermal module 24 according to the present embodiment is configured separately from the fans 36 and thus positioning of the motherboard 25 is not easy. In this case, the electronic apparatus 10 may have a configuration that positioning pins are installed on the motherboard 25 to position the thermal module 24, for example. However, many components are mounted on the motherboard 25. For this purpose, it is not easy to secure the installation space of the positioning pins on the motherboard 25. In this regard, the electronic apparatus 10 can position the thermal module 24 by using the stud parts 42 mounted on the motherboard 25 for fastening the thermal module 24. Therefore, the electronic apparatus 10 also enables the reduction of the number of parts and the miniaturization of the motherboard 25 etc.

The thermal module 24 can include the metal plate 30 that can diffuse the heat of the CPU 25a. In this case, the positioning parts 40 may be provided on the metal plate 30. In other words, the metal plate 30 is a copper plate, for example, and processing and molding of the positioning parts 40 are also easy. For this purpose, the positioning parts 40 further improves the installation cost and installation efficiency.

The pair of stud parts 42A and 42B can be arranged side by side along the edge 30b of the metal plate 30. The metal plate 30 can include the pair of arm portions 60 and 60 that protrudes toward the stud parts 42A and 42B from the edge 30b. Each of the positioning parts 40 can include the first end surface 40a along the X direction and the second end surface 40b along the Y direction, and be formed by cutting out the tip of the corresponding arm portion 60. By doing so, the positioning parts 40 can be formed with a simple configuration. Moreover, because the positioning parts 40 are located at the tips of the arm portions 60 protruding from the edge 30b, workability when the positioning parts are abutted against the stud parts 42A and 42B is improved.

The second end surfaces 40b of the pair of positioning parts 40 can be located on the opposite side to the side where the outer peripheral surfaces 42a of the pair of stud parts 42A and 42B face each other. In other words, the second end surfaces 40b are not arranged between the stud parts 42A and 42B, but can be respectively arranged on the outsides of the stud parts 42A and 42B. By doing so, a positioning work can be performed between the second end surfaces 40b and 40b of the left and right positioning parts 40 by simultaneously gripping the two stud parts 42A and 42B. As a result, the positioning work efficiency of the thermal module 24 is further improved.

In this case, the exhaust path 50 from the discharge ports 36b of the fans 36 toward the exhaust port 48a can be formed between the pair of stud parts 42A and 42B. By doing so, the second end surfaces 40b of the positioning parts 40 can be arranged on the outside that is the opposite side to the inside corresponding to the exhaust path 50 side when being viewed from the stud parts 42A and 42B. As a result, the positioning parts 40 can be prevented from blocking up the exhaust path 50 to improve air-blow efficiency from the fans 36. When the exhaust path 50 is not blocked up, the positioning parts 40 may be configured to include the pair of second end surfaces 40b having a U-shape instead of an L-shape, for example.

When the standing direction of the stud parts 42 is used as a reference, the arm portions 60 can include the step portions 60a for arranging the positioning parts 40 below the top surfaces 42b of the stud parts 42 (on the Z1 side). As a result, even if the metal plate 30 is located above the stud parts 42, the positioning parts 40 can be reliably arranged to face the outer peripheral surfaces 42a.

The thermal module 24 can include the flat spring members 34a for pressing the thermal module against the CPU 25a. In this case, the thermal module 24 can be configured to be fixed to the motherboard 25 by fastening the flat spring members 34a to the stud parts 42. By doing so, the thermal module 24 can be pressed against the CPU 25a to improve the cooling efficiency of the CPU 25a. Furthermore, the flat spring members 34a and the arm portions 60 are composed of separate members, and thus fastening the thermal module 24 to the stud parts 42 and positioning the thermal module 24 with the stud parts 42 are easily performed.

Note that the present invention is not limited to the embodiment described above, and the embodiment can be freely changed without departing from the scope of the present invention.

As described above, the stud parts 42A and 42B arranged on the Y2 side of the thermal module 24 in the X direction have been illustrated as the stud parts 42 for positioning the positioning parts 40. However, the pair of stud parts 42 for positioning the positioning parts 40 may be arranged on the Y1 side of the thermal module 24 in the X direction. Furthermore, the pair of stud parts 42 for positioning the positioning parts 40 may be arranged to straddle the thermal module 24 in the Y direction.

1. An electronic apparatus comprising:
a board having a surface mounted thereon with at least a pair of stud parts and a heating element; and
a thermal module that covers the heating element and the surface of the board, the thermal module being fixed to the board by the at least pair of stud parts, wherein
the thermal module includes a pair of positioning parts that respectively abuts respective outer peripheral surfaces of the pair of stud parts, and
the pair of positioning parts are configured to position the thermal module on the surface of the board in a first direction and a second direction perpendicular to the first direction.

2. The electronic apparatus according to claim 1, wherein
the thermal module includes a metal plate that is configured to diffuse heat of the heating element, and
the pair of positioning parts are on the metal plate.

3. The electronic apparatus according to claim 2, wherein
the pair of stud parts are arranged side-by-side along one edge of the metal plate,
the metal plate includes a pair of arm portions that protrudes from the one edge and towards the stud parts, and
each of the positioning parts includes a first end surface along the first direction and a second end surface along the second direction.

4. The electronic apparatus according to claim 3, wherein
the one edge of the metal plate extends along the first direction, and
the second end surfaces of the pair of positioning parts are on opposite sides of the outer peripheral surfaces that face each other.

5. The electronic apparatus according to claim 4, further comprising:
a chassis that houses the board and the thermal module; and
a pair of fans mounted inside the chassis and straddles the thermal module therebetween, the pair of fans having discharge ports capable of discharging air toward the thermal module on side surfaces facing each other, wherein
the chassis includes an exhaust port between the pair of fans, and
an exhaust path from the discharge ports of the pair of fans and towards the exhaust port is between the pair of stud parts.

6. The electronic apparatus according to claim 3, wherein
the thermal module includes a heat transport device stacked on a surface of the heating element via a thermal conductive member and includes the metal plate stacked on the heat transport device,
the metal plate is above top surfaces of the stud parts, and
the arm portions respectively include step portions configured to position the positioning parts below the top surfaces of the stud parts.

7. The electronic apparatus according to claim 1, wherein
the thermal module includes flat spring members for pressing the thermal module against the heating element, and
the thermal module is fixed to the board by the flat spring members fastened to the stud parts.
